(19) United States
(12) Patent Application Publication
(10) Pub. No.: US 2026/0334338 A1
(43) Pub. Date: Oct. 22, 2026

(54) SEMICONDUCTOR PACKAGE INCLUDING UNDER BUMP METALLIZATION

(71) Applicant: SAMSUNG ELECTRONICS CO., LTD., Suwon-si (KR)

(72) Inventors: Jae-Ean LEE, Suwon-si (KR); Kyunghun LEE, Suwon-si (KR); Gyujin CHOI, Suwon-si (KR)

(73) Assignee: SAMSUNG ELECTRONICS CO., LTD., Suwon-si (KR)

(21) Appl. No.: 19/347,889

(22) Filed: Oct. 2, 2025

(30) Foreign Application Priority Data
Apr. 21, 2025 (KR) 10-2025-0051819

(51) Int. Cl. H10W 90/00; H10W 70/60; H10W 70/65; H10W 70/66; H10W 74/15

(52) U.S. Cl. CPC H10W 90/701; H10W 70/611; H10W 70/65; H10W 70/66; H10W 74/15; H10W 90/00; H10W 90/724; H10W 90/734

(57) ABSTRACT

The present disclosure provides a semiconductor package including a passivation layer; an under bump metallization including a seed layer and a conductive layer disposed on the seed layer, penetrating the passivation layer and extending onto the upper surface of the passivation layer; an external connection terminal disposed on the lower surface of the above under bump metallization; a redistribution structure disposed on the upper surface of the passivation layer and covering the under bump metallization; and a semiconductor chip disposed on the upper surface of the above redistribution structure. The seed layer includes a first region disposed between the external connection terminal and the conductive layer and a second region disposed between the passivation layer and the conductive layer.

### CROSS-REFERENCE TO RELATED APPLICATION

This application claims priority to and the benefit of Korean Patent Application No. 10-2025-0051819 filed with the Korean Intellectual Property Office on Apr. 21, 2025, the entire contents of which are incorporated herein by reference.

### BACKGROUND OF THE INVENTION

### (a) Field of the Invention

The present disclosure relates to a semiconductor package.

### (b) Description of the Related Art

Semiconductor packages may have solder bumps formed for electrical connections to other components and for package mounting. Previously, C4 bumps formed through a solder ball attach (SBA) process were widely used, but as the semiconductor packages have become more high-performance and have become finer pitched, pillar bumps formed with solder caps on copper (Cu) pillars are being applied.

### SUMMARY OF THE INVENTION

Embodiments of the present disclosure seek to provide a semiconductor package capable of improving an alignment between external connection terminals and under bump metallizations.

Embodiments of the present disclosure aim to provide a semiconductor package capable of reducing a cost loss caused by having to discard the entire package due to defects occurring after a mounting of a semiconductor chip.

Embodiments of the present disclosure seek to provide a semiconductor package with an improved reliability by strengthening the interfacial adhesion between an under bump metallization and a passivation layer.

As an embodiment, the present disclosure provides a semiconductor package including a passivation layer; an under bump metallization including a seed layer and a conductive layer disposed on the seed layer, penetrating the passivation layer and extending onto an upper surface of the passivation layer; an external connection terminal disposed on a lower surface of the under bump metallization; a redistribution structure disposed on an upper surface of the passivation layer and covering the under bump metallization; and a semiconductor chip disposed on an upper surface of the redistribution structure. The seed layer includes a first region disposed between the external connection terminal and the conductive layer and a second region disposed between the passivation layer and the conductive layer.

As another embodiment, the present disclosure provides a semiconductor package including a passivation layer; a plurality of under bump metallizations including a seed layer and a conductive layer disposed on the seed layer, penetrating the passivation layer and extending onto an upper surface of the passivation layer; a plurality of external connection terminals disposed on a lower surface of the plurality of under bump metallizations and electrically connected to the plurality of under bump metallizations, respectively; a redistribution structure disposed on an upper surface of the passivation layer, covering the plurality of under bump metallizations, and electrically connected to the plurality of under bump metallizations; a plurality of semiconductor chips disposed side by side on an upper surface of the redistribution structure; and a encapsulant covering at least a portion of each of the plurality of semiconductor chipsThe redistribution structure electrically connects two or more of the plurality of semiconductor chips, and the seed layer includes a first region disposed between each of the plurality of external connection terminals and the conductive layer, and a second region disposed between the passivation layer and the conductive layer.

As another embodiment, the present disclosure provides a semiconductor package, including a passivation layer; a plurality of under bump metallizations including a seed layer and a conductive layer disposed on the seed layer, penetrating the passivation layer and extending onto an upper surface of the passivation layer; a plurality of external connection terminals disposed on a lower surface of the plurality of under bump metallizations and electrically connected to the plurality of under bump metallizations, respectively; a first redistribution structure disposed on an upper surface of the passivation layer, covering the plurality of under bump metallizations, and electrically connected to the plurality of under bump metallizations; a bridge die disposed on an upper surface of the first redistribution structure; a first encapsulant covering at least a portion of the bridge die; a second redistribution structure disposed on the first encapsulant and electrically connected to the bridge die and the first redistribution structure; a plurality of semiconductor chips disposed side by side on an upper surface of the second redistribution structure and electrically connected to the second redistribution structure; and a second encapsulant covering at least a portion of each of the plurality of semiconductor chips. The bridge die electrically connects two or more of the plurality of semiconductor chips, and the seed layer includes a first region disposed between each of the plurality of external connection terminals and the conductive layer, and a second region disposed between the passivation layer and the conductive layer.

Embodiments of the present disclosure may provide the semiconductor package capable of improving the alignment between the external connection terminal and the under bump metallization.

Embodiments of the present disclosure may provide the semiconductor package that may reduce a cost loss caused by having to discard the entire package due to defects occurring after mounting of the semiconductor chip.

Embodiments of the present disclosure may provide the semiconductor package with the improved reliability by strengthening the interfacial adhesion between the under bump metallization and the passivation layer.

### BRIEF DESCRIPTION OF THE DRAWINGS

FIG. 1 is a cross-sectional view of a semiconductor package according to one embodiment.

FIG. 2 is an enlarged view of a portion A in FIG. 1.

FIG. 3 is an enlarged view showing a portion A’ of a modified example corresponding to the portion A of FIG. 1.

FIG. 4 is a cross-sectional view of a semiconductor package according to another embodiment.

FIG. 5 is an enlarged view of a portion B of FIG. 4.

FIG. 6 is an enlarged view showing a portion B’ of a modified example corresponding to the portion Bof FIG. 4.

FIG. 7 is a cross-sectional view of a semiconductor package according to another embodiment.

FIGS. 8 to 23 are cross-sectional views sequentially showing a method for manufacturing a semiconductor package according to one embodiment.

### DETAILED DESCRIPTION OF THE EMBODIMENTS

Hereinafter, various embodiments of the present disclosure will be described in detail with reference to the attached drawings so that a person having ordinary skill in the art to which the present disclosure pertains can easily implement the present disclosure. The present disclosure may be embodied in many different forms and is not limited to the embodiments set forth herein.

Descriptions of parts not related to the present disclosure are omitted, and like reference numerals designate like elements throughout the specification.

Further, since sizes and thicknesses of constituent members shown in the accompanying drawings are arbitrarily given for better understanding and ease of description, the present invention is not limited to the illustrated sizes and thicknesses. In the drawings, the thickness of layers, films, panels, regions, etc., are exaggerated for clarity. In the drawings, for better understanding and ease of description, the thicknesses of some layers and areas are exaggerated.

Throughout this specification and the claims that follow, when it is described that an element is “coupled” to another element, the element may be “directly coupled” to the other element or “indirectly coupled” to the other element through a third element. From a similar perspective, this includes not only being "physically connected" but also being "electrically connected".

Also, it will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, in the specification, the phrase “on a flat surface” means when an object portion is viewed from above, and the phrase “on a cross-section” means when a cross-section taken by vertically cutting an object portion is viewed from the side.

Additionally, throughout the specification, the sequential numbers first, second, etc. are used to distinguish certain components from other identical or similar components, and are not necessarily intended to refer to specific components. Thus, a component referred to as a first component in a particular part of this specification may be referred to as a second component in another part of this specification.

Additionally, throughout the specification, a singular reference to a component includes a plural reference to that component unless specifically stated otherwise. For example, "an insulating layer" may be used to mean not only one insulating layer, but also a plurality of insulating layers, such as two, three or more.

Additionally, throughout the specification, references to directions such as upper surface, upper side, upper part, lower surface, lower side, lower part, etc. are described to aid explanation and understanding based on the drawings.

Hereinafter, semiconductor packages according to embodiments of the present disclosure will be described with reference to attached drawings.

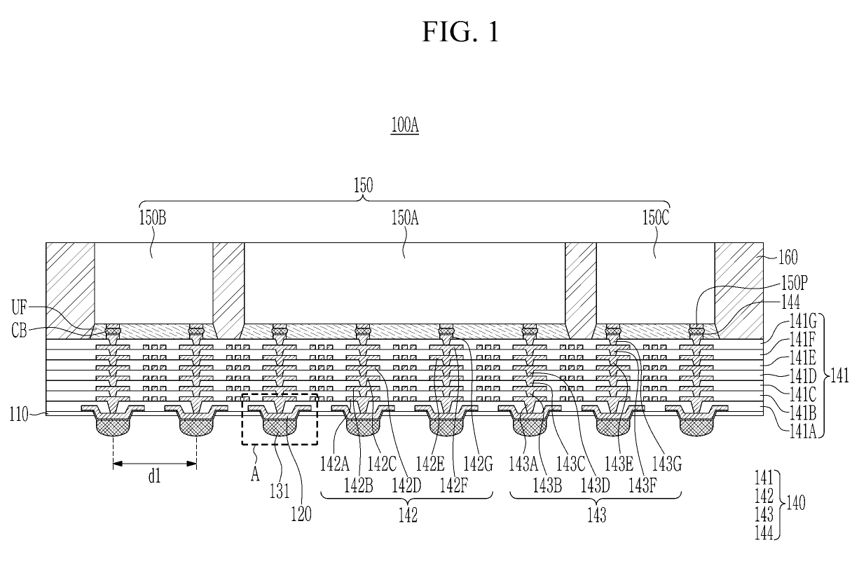

FIG. 1 is a cross-sectional view of a semiconductor package according to one embodiment.

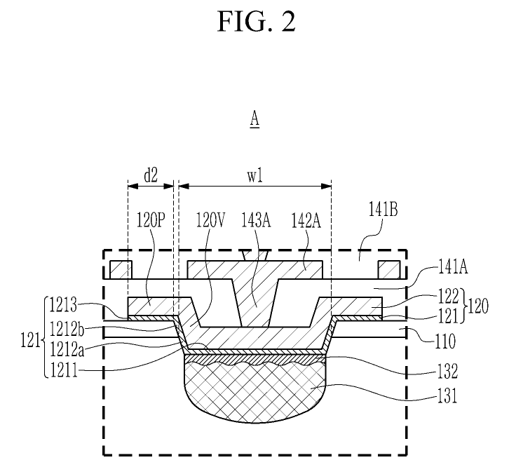

FIG. 2 is an enlarged view of a portion A in FIG. 1.

Referring to FIGS. 1 and 2, a semiconductor package 100A according to one embodiment includes a passivation layer 110, an under bump metallization 120, an external connection terminal 131, a redistribution structure 140, a semiconductor chip 150, and an encapsulant 160.

The passivation layer 110 may protect the surface of the redistribution structure 140. The passivation layer 110 may be disposed on the lower surface of the redistribution structure 140 and be in contact with the lowest insulating layer 141A of the redistribution structure 140. An insulating material may be used as the material for the passivation layer 110. In some embodiments, the passivation layer 110 may include a photo-imageable dielectric (PID) that is capable of a photolithography process. For example, the passivation layer 110 may include a photo-sensitive polyimide (PSPI). When the passivation layer 110 includes PID, the under bump metallization 120 having a fine pitch and the external connection terminal 131 may be formed. However, the material of the passivation layer 110 is not limited thereto, and the passivation layer 110 may include other insulating materials such as a thermoplastic resin such as polyimide (PI), a thermosetting resin such as epoxy, and a solder resist.

The under bump metallization 120 physically and/or electrically connects the redistribution structure 140 and the external connection terminal 131, and may prevent cracks in the external connection terminal 131 and improve a connection reliability. The under bump metallization 120 may penetrate the passivation layer 110 and extend onto the upper surface of the passivation layer 110. The under bump metallization 120 may protrude from the lower surface of the passivation layer 110, but is not limited thereto.

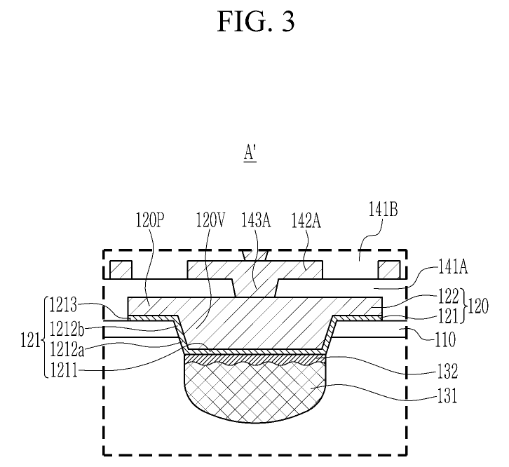

The region of the under bump metallization 120 penetrating the passivation layer 110 may be referred to as a via region 120V, and the region positioned on the passivation layer 110 may be referred to as a pad region 120P. In the present disclosure, the via region 120V and the pad region 120P are introduced to specifically describe the regions of the under bump metallization 120 by distinguishing them, and these regions may be formed integrally and may not have boundaries with each other. When the under bump metallization 120 protrudes from the lower surface of the passivation layer 110, the via region 120V may be a protruding via that includes a region protruding from the lower surface of the passivation layer 110. In some embodiments, the via region 120V may be a plated-via formed along the wall and bottom surfaces of an opening formed in the passivation layer 110, and the pad region 120P may have a shape (e.g., a ring shape) with a recess in the middle. In some embodiments, the via region 120V may be a filled-via that fills an opening formed in the passivation layer 110, and the pad region 120P may have a plate shape (e.g., a circular plate shape) with a filled center space (referring to FIG. 3). When the pad area 120P has a plate shape, it may be easy to control the depth of the via hole for forming the first via 143A.

In the via region 120V, the width w1 of the under bump metallization may narrow from the upper side to the lower side. When the width w1 of the via region 120V is formed to narrow from the upper side to the lower side, the interfacial adhesion between the passivation layer 110 and the under bump metallization 120 may be improved. However, according to another embodiment, the width w1 of the under bump metallization in the via area 120V may be constant or may widen from the upper side to the lower side.

The distance d2 from the outer edge of the via region 120V to the outer edge of the pad region 120P on the upper surface of the passivation layer 110 may be 20 µm or more and 40 µm or less. The distance d2 from the outer end of the via region 120V to the outer end of the pad region 120P on the upper surface of the passivation layer 110 may also be described as the width on the cross-sectional of the pad region 120P in contact with the upper surface of the passivation layer 110. If the distance d2 from the outer end of the via region 120V to the outer end of the pad region 120P on the upper surface of the passivation layer 110 is less than 20 µm, it is difficult to secure the sufficient adhesion between the under bump metallization 120 and the passivation layer 110, and if it exceeds 40 µm, it may be difficult to achieve a fine pitch.

The under bump metallization 120 may include a seed layer 121 and a conductive layer 122 disposed on the seed layer 121. The thickness of the seed layer 121 may be thinner than the thickness of the conductive layer 122. For example, the thickness of the seed layer 121 may be several to several hundred nanometers, and/or the thickness of the conductive layer 122 may be several to several tens of microns. Here, the thickness means the thickness in the direction perpendicular to the surface on which the seed layer 121 and the conductive layer 122 are formed. As described below, the under bump metallization 120 may be manufactured by forming an opening in the passivation layer 110 and sequentially forming the seed layer 121 and the conductive layer 122 within the opening so as to be extended onto the passivation layer 110.

Conductive materials may be used as the materials for each of the seed layer 121 and the conductive layer 122. For example, each of the seed layer 121 and the conductive layer 122 may include a metal such as aluminum (Al), copper (Cu), titanium (Ti), tungsten (W), gold (Au), platinum (Pt), silver (Ag), tin (Sn), chromium (Cr), palladium (Pd), or an alloy of two or more of these. For example, the seed layer 121 may include titanium (Ti) and/or the conductive layer 122 may include copper (Cu). In some embodiments, the seed layer 121 may have a Ti/Cu structure including a titanium (Ti) layer and a copper (Cu) layer disposed on the titanium layer, and the conductive layer 122 may include copper (Cu).

The seed layer 121 may include a first region 1211 disposed on the lower surface of the via region 120V, second regions 1212a and 1212b disposed on the wall surface of the via region 120V, and a third region 1213 disposed on the lower surface of the pad region 120P. It may also be described that the first region 1211 may cover the lower surface of the conductive layer 122 in the via region 120V, the second regions 1212a and 1212b may cover the side surface of the conductive layer 122 in the via region 120V, and the third region 1213 may cover the lower surface of the conductive layer 122 in the pad region 120P. The second regions 1212a and 1212b may include a second-first region 1212a disposed on the lower side and not covered with the passivation layer 110 and a second-second region 1212b disposed on the upper side and covered with the passivation layer 110. The first region 1211, the second-first region 1212a, the second-second region 1212b, and the third region 1213 may be sequentially disposed along the bottom surface and the wall surface of the via region 120V and the lower surface of the pad region 120P and may be connected to each other. Considering the components adjacent to the under bump metallization 120, the first region 1211 may be positioned between the external connection terminal 131 and the conductive layer 122, and the second-second region 1212b and the third region 1213 may be positioned between the passivation layer 110 and the conductive layer 122. The second-second region 1212b and the third region 1213 positioned between the passivation layer 110 and the conductive layer 122 may improve the interfacial adhesion between the passivation layer 110 and the under bump metallization 120. For example, the seed layer 121 can improve the interfacial adhesion between the passivation layer 110 and the under bump metallization 120 by including titanium (Ti). In the present disclosure, the first region 1211, the second-first region 1212a, the second-second region 1212b, and the third region 1213 are introduced to specifically describe the regions of the seed layer 121 by dividing them, and these regions may be formed integrally and may not have boundaries with each other.

An intermetallic compound (IMC) 132 may be formed between the under bump metallization 120 and the external connection terminal 131. The intermetallic compound 132 may be formed by an intermetallic reaction between the first region 1211 of the seed layer 121 and the external connection terminal 131. For example, the intermetallic compound 132 may be formed by a reaction between titanium (Ti) of the seed layer 121 and the Sn-Ag alloy of the external connection terminal 131. The intermetallic compound 132 may improve the interfacial adhesion between the under bump metallization 120 and the external connection terminal 131, thereby preventing an interfacial peeling and improving a mechanical strength and a reliability. Additionally, the intermetallic compound 132 may prevent interface cracks by preventing the excessive diffusion of the conductive layer 122.

The external connection terminal 131 may be disposed on the lower surface of the under bump metallization 120 and be electrically connected to the under bump metallization 120. The external connection terminal 131 may physically and/or electrically connect the semiconductor package 100A to other components. For example, the external connection terminal 131 may physically and/or electrically connect the semiconductor package 100A to another component (e.g., a printed circuit board) on which the semiconductor package 100A is mounted. The external connection terminals 131 may have a fine pitch. For example, the distance d1 between the centers of the adjacent external connection terminals 131 among the external connection terminals 131 on the cross-section may be 130 µm or less. As a specific example, the distance d1 between the centers of the adjacent external connection terminals 131 among the external connection terminals 131 on the cross section may be 80 µm or more and 130 µm or less. As described later, the external connection terminal 131 may be formed to have a fine pitch by forming the opening in the passivation layer 110 by using a photolithography process and plating a conductive material within the opening. A conductive material may be used as the material for the external connection terminal 131. For example, the external connection terminal 131 may include a solder including a Sn-Ag alloy, a Sn-Ag-Cu alloy, etc. The size, number, spacing, arrangement, etc. of the external connection terminal 131 are not particularly limited.

The redistribution structure 140 may be disposed on the upper surface of the passivation layer 110 to cover the under bump metallization 120 and be electrically connected to the under bump metallization 120. The redistribution structure 140 may be electrically connected to the semiconductor chip 150 placed on the upper side thereof and rewiring a connection pad 150P of the semiconductor chip 150. The redistribution structure 140 may include an insulating layer 141, a wiring layer 142, and a via 143. For example, the redistribution structure 140 includes a first insulating layer 141A, a first wiring layer 142A disposed on the first insulating layer 141A, a first via 143A penetrating the first insulating layer 141A and electrically connecting the under bump metallization 120 and the first wiring layer 142A, a second insulating layer 141B disposed on the first insulating layer 141A, a second wiring layer 142B disposed on the second insulating layer 141B, a second via 143B penetrating the second insulating layer 141B and electrically connecting the first wiring layer 142A and the second wiring layer 142B, a third insulating layer 141C disposed on the second insulating layer 141B, a third wiring layer 142C disposed on the third insulating layer 141C, a third via 143C penetrating the third insulating layer 141C and electrically connecting the second wiring layer 142B and the third wiring layer 142C, a fourth insulating layer 141D disposed on the third insulating layer 141C, a fourth wiring layer 142D disposed on the fourth insulating layer 141D, a fourth via 143D electrically connecting the third wiring layer 142C and the fourth wiring layer 142D while penetrating the fourth insulating layer 141D, a fifth insulating layer 141E disposed on the fourth insulating layer 141D, a fifth wiring layer 142E disposed on the fifth insulating layer 141E, a fifth via 143E electrically connecting the fourth wiring layer 142D and the fifth wiring layer 142E while penetrating the fifth insulating layer 141E, a sixth insulating layer 141F disposed on the fifth insulating layer 141E, a sixth wiring layer 142F disposed on the sixth insulating layer 141F, a sixth via 143F penetrating the sixth insulating layer 141F and electrically connecting the fifth wiring layer 142E and the sixth wiring layer 142F, a seventh insulating layer 141G disposed on the sixth insulating layer 141F, a seventh wiring layer 142G disposed on the seventh insulating layer 141G, and a seventh via 143G penetrating the seventh insulating layer 141G and electrically connecting the sixth wiring layer 142F and the seventh wiring layer 142G. However, the number of the layers of the redistribution structure 140 may be less or more than that shown in the drawing.

The insulating layers 141 can be laminated. The first insulating layer 141A positioned at the lowest side among the insulating layers 141 may integrally cover the under bump metallization 120 on the passivation layer 110. An insulating material may be used as the material for the insulating layer 141. In some embodiments, the insulating layer 141 may include a PID capable of a photolithography process. For example, the insulating layer 141 may include photosensitive polyimide (PSPI). When the insulating layer 141 includes a PID, a fine pitch may be implemented through a photo via formation. In some embodiments, the insulating layer 141 may include an organic insulating material. For example, the insulating layer 141 may include a thermoplastic resin such as polyimide (PI), a thermosetting resin such as epoxy or polybenzoxazole (PBO), or a resin in which these resins are mixed with an inorganic filler (e.g., Ajinomoto Build-up Film (ABF)). In some embodiments, the insulating layer 141 may include an inorganic insulating material. For example, the insulating layer 141 may include an oxide such as silicon oxide or a nitride such as silicon nitride. When the insulating layer 141 is multi-layered, the material of each insulating layer 141 may be the same or different. When the insulating layer 141 is multilayered, the insulating layers 141 may have boundaries with each other, may have unclear boundaries, or may be integrated and have no boundaries. The insulating layer 141 may be formed by a deposition or a lamination process, but is not limited thereto.

Each wiring layer 142 can be placed on each insulating layer 141. The wiring layer 142 may include wiring patterns, and the wiring patterns of each wiring layer 142 may be connected to each other to form a wiring that performs the designed function. For example, the wiring patterns of each wiring layer 142 may be connected to each other to form a signal line for a signal transmission, a power line for a power supply, or a ground line for a ground provision. Additionally, the wiring layer 142 may include a via pad connected to a via 143, a connection pad for electrical connection with other components, etc. A conductive material may be used as the material for the wiring layer 142. For example, the wiring layer 142 may include a metal such as aluminum (Al), copper (Cu), titanium (Ti), tungsten (W), gold (Au), platinum (Pt), silver (Ag), tin (Sn), chromium (Cr), palladium (Pd), or an alloy of two or more of these.

At least one surface treatment layer 144 may be placed on the uppermost wiring layer 142G that functions as a connection pad among the wiring layers 142. The surface treatment layer 144 may be composed of a single layer or multiple layers. For example, the surface treatment layer 144 may include a first surface treatment layer including nickel (Ni) and a second surface treatment layer disposed on the first surface treatment layer and including gold (Au). The first surface treatment layer may prevent a formation of an intermetallic compound (IMC) due to the diffusion between the uppermost wiring layer 142G and the second surface treatment layer, and the second surface treatment layer may prevent the surface oxidation of the uppermost wiring layer 142G and improve the electrical reliability.

Each via 143 may penetrate at least one of the insulating layers 141 and physically and/or electrically connect the wiring layers 142 disposed in the different layers. The first via 143A positioned at the lowest side among the vias 143 may be in contact with the under bump metallization 120. For example, the first via 143A may be in contact with the via region 120V of the under bump metallization 120. The diameter of the first via 143A connected to the under bump metallization 120 may be greater than the diameters of the other vias 143B, 143C, 143D, 143E, 143F, and 143G, but is not limited thereto. The thickness of the first via 143A may be greater than the thickness of the other vias 143B, 143C, 143D, 143E, 143F, and 143G, but is not limited thereto.

The via 143 may have various shapes, such as a tapered shape with a width that narrows from one side to the other side, or a cylindrical shape. A conductive material may be used as the material for the via 143. For example, the via 143 may include a metal such as aluminum (Al), copper (Cu), titanium (Ti), tungsten (W), gold (Au), platinum (Pt), silver (Ag), tin (Sn), chromium (Cr), palladium (Pd), or an alloy of two or more of these. The via 143 may be a filled via in which the interior of the via hole is completely filled with a conductive material, or it may be a plated via in which the conductive material is formed along the wall and bottom surfaces of the via hole.

The via 143 may be formed integrally with the wiring layer 142 located on the upper side thereof. For example, the via 143 and the wiring layer 142 may be formed by forming a via hole penetrating the insulating layer 141 and filling the via hole with a conductive material so that it extends onto the insulating layer 141. The via 143 and the wiring layer 142 may include a first conductive layer functioning as a seed layer and a second conductive layer disposed on the first conductive layer. The first conductive layer may extend along the surface of the insulating layer 141, the wall surface and the bottom surface of the via hole. In some embodiments, the first conductive layer may be formed by a physical vapor deposition (PVD), and the second conductive layer may be formed by an electrolytic plating or an electroless plating. In some embodiments, the first conductive layer may have a Ti/Cu structure including a titanium (Ti) layer and a copper (Cu) layer disposed on the titanium layer, and the second conductive layer may include copper (Cu).

The semiconductor chip 150 may be placed on the upper surface of the redistribution structure 140 and be electrically connected to the redistribution structure 140. In some embodiments, a plurality of semiconductor chips 150 may be disposed on the redistribution structure 140. For example, a first semiconductor chip 150A, a second semiconductor chip 150B, and a third semiconductor chip 150C may be placed on the redistribution structure 140. The semiconductor chips 150 may be placed side by side with each other. Two or more of the second semiconductor chips 150 may be electrically connected by the redistribution structure 140. For example, the redistribution structure 140 may function as an interposer for providing a 2.3D package.

The semiconductor chip 150 may be an integrated circuit (IC) chip in which a large number (e.g., millions) of individual elements that constitute a circuit are integrated. The individual elements of the semiconductor chip 150 may be formed on a semiconductor substrate and may include, for example, at least one of a metal-oxide-semiconductor field effect transistor (MOSFET), a bipolar junction transistor (BJT), a diode, a light emitting diode (LED), a capacitor, an inductor, and a resistor. The semiconductor substrate of the semiconductor chip 150 may include a semiconductor material. For example, the semiconductor substrate of the semiconductor chip 150 may include a semiconductor element such as silicon (Si), germanium (Ge), or a compound semiconductor such as gallium arsenide (GaAs), indium arsenide (InAs), or silicon carbide (SiC). The semiconductor substrate of the semiconductor chip 150 may have a shape that is approximately rectangular, for example, a square or a rectangle, but is not limited thereto. The semiconductor chip 150 may have connection pads 150P for electrically connecting the semiconductor chip 150 to other components. A conductive material may be used as the material for the connection pad 150P. For example, the connection pad 150P may include a metal such as aluminum (Al), copper (Cu), titanium (Ti), tungsten (W), gold (Au), platinum (Pt), silver (Ag), tin (Sn), chromium (Cr), palladium (Pd), or an alloy of two or more of these. The surface on which the connection pad 150P of the semiconductor chip 150 is disposed may be referred to as an active surface, and the surface opposite to the active surface may be referred to as an inactive surface. In some embodiments, the semiconductor chip 150 may be placed in a face down shape so that the active surface faces the redistribution structure 140. A passivation layer may be formed on the active surface of the semiconductor chip 150 to protect the semiconductor chip 150, and the passivation layer may have openings that expose the connection pads 150P. An insulating material may be used as the material for the passivation layer of the semiconductor chip 150. For example, the passivation layer of the semiconductor chip 150 may include an inorganic insulating material such as silicon oxide, silicon nitride, or silicon carbide nitride (SiCN), or an organic insulating material such as polyimide (PI), polybenzoxazole (PBO), or benzocyclobutene (BCB). The passivation layer of the semiconductor chip 150 may be composed of one or more layers.

The type of each semiconductor chip 150 is not particularly limited and may be a logic chip or a memory chip. The above logic chip may include at least one of an application processor (AP), a microprocessor, a central processing unit (CPU), a graphic processing unit (GPU), a neural processing unit (NPU), an application specific integrated circuit (ASIC), and a system on chip (SoC). The above memory chip may include at least one of high bandwidth memory (HBM), dynamic random access memory (DRAM), static random access memory (SRAM), flash memory, read-only memory (ROM), and magnetic random access memory (MRAM). When the plurality of semiconductor chips 150 are configured, the types of the plurality of semiconductor chips 150 may be the same or different. For example, the first semiconductor chip 150A may be a logic chip such as an ASIC, and the second semiconductor chip 150B and the third semiconductor chip 150C may be memory chips such as an HBM, but are not limited thereto.

In some embodiments, the semiconductor chip 150 may be physically and/or electrically connected to the redistribution structure 140 via chip bumps CB. A conductive material may be used as the material for chip bumps (CB). For example, the chip bump CB may include a solder including a Sn-Ag alloy, a Sn-Ag-Cu alloy, etc. Alternatively, the chip bump CB may include a metal or an alloy of metals. The chip bump CB may consist of single or multiple layers. In some embodiments, the chip bump CB may be a C4 bump. In some embodiments, the chip bump CB may be a filler bump including a conductive pillar and a conductive cap disposed on the conductive pillar. Metals such as copper (Cu) and aluminum (Al) may be used as materials for the above conductive filler. A solder may be used as the material for the above conductive cap. There are no special restrictions on the size, number, spacing, or arrangement of the chip bump CB.

The chip bumps CB may be covered with an underfill resin UF that fills at least a portion of the space between the redistribution structure 140 and the semiconductor chip 150. The underfill resin UF may also extend onto the lower side of the semiconductor chip 150. The underfill resin UF may fix the semiconductor chip 150 on the redistribution structure 140 and relieve a stress caused by a difference in a coefficient of a thermal expansion (CTE) between the semiconductor chip 150 and the redistribution structure 140. The underfill resin UF may include an insulating material such as epoxy resin, and may further contain an inorganic filler such as silica or alumina, if necessary.

The encapsulant 160 may cover at least a portion of each of the semiconductor chips 150 and protect the semiconductor chips 150. For example, the encapsulant 160 may cover the side of each semiconductor chip 150. An insulating material may be used as the material for the encapsulant 160. For example, the encapsulant 160 may include an epoxy molding compound (EMC). Alternatively, the encapsulant 160 may include other insulating materials, such as a thermosetting resin such as epoxy, a thermoplastic resin such as polyimide (PI), etc. The process of molding the semiconductor chip 150 with the encapsulant 160 may be performed, for example, by a compression molding or a transfer molding. In some embodiments, the upper surface of the semiconductor chip 150 may be exposed to the upper surface of the encapsulant 160. The upper surface of the semiconductor chip 150 may be coplanar with the upper surface of the encapsulant 160. The upper surface of the semiconductor chip 150 may be exposed to the upper surface of the encapsulant 160 by grinding and removing a portion of the encapsulant 160. By exposing the upper surface of the semiconductor chip 150 to the upper surface of the encapsulant 160, a heat dissipation characteristics of the semiconductor package 100A may be improved. According to an embodiment, the encapsulant 160 may be omitted, or another component may protect the semiconductor chip 150 in place of the encapsulant 160.

Meanwhile, the semiconductor package may have solder bumps formed for an electrical connection with other components and for package mounting. Previously, C4 bumps formed through a solder ball attach (SBA) process were widely used, but as the semiconductor package has become more high-performance and has become finer pitched, pillar bumps formed with solder caps on copper (Cu) pillars are being applied. The filler bump may be manufactured, for example, by sequentially forming the copper filler and the solder cap on the lower surface of the redistribution structure on which the semiconductor chip is mounted through a plating process and then performing a solder reflow process. During the plating process for forming the copper filler and the solder cap, a misalignment of the copper filler on the redistribution structure, a misalignment of the solder cap on the copper filler, and a gap height defect may occur. The defects that occur during the manufacturing process of the copper filler and the solder caps may also lead to a solder shift, a solder bridge, and a joint height defect after the solder reflow process. If the defect occurs in the process after the semiconductor chip is mounted, the entire package including the semiconductor chip must be discarded, and in the case of the package using the expensive semiconductor chips, this may result in a significant cost loss.

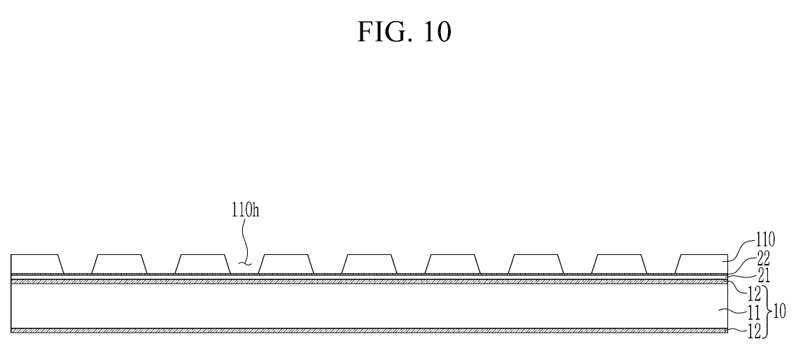

According to the present disclosure, by sequentially forming an external connection terminal 131 and an under bump metallization 120 within the same opening of a passivation layer 110, alignment therebetween can be improved. As described below, the external connection terminal 131 and the under bump metallization 120 are formed before the mounting of the semiconductor chip 150, and therefore, even if the defect occurs during the manufacturing process of the external connection terminal 131 and the under bump metallization 120, the cost loss due to the defect may be reduced by discarding only a portion of the package excluding the semiconductor chip 150. In addition, since the seed layer 121 is placed between the passivation layer 110 and the conductive layer 122, the interfacial adhesion between the under bump metallization 120 and the passivation layer 110 is strengthened, thereby improving the reliability. In addition, by forming an opening 110h in the passivation layer 110 and filling the opening with a conductive material in a manner similar to the method of forming the redistribution structure 140, the external connection terminal 131 and the under bump metallization 120 may be formed (referring to FIG. 10 to FIG. 12), thereby simplifying the process.

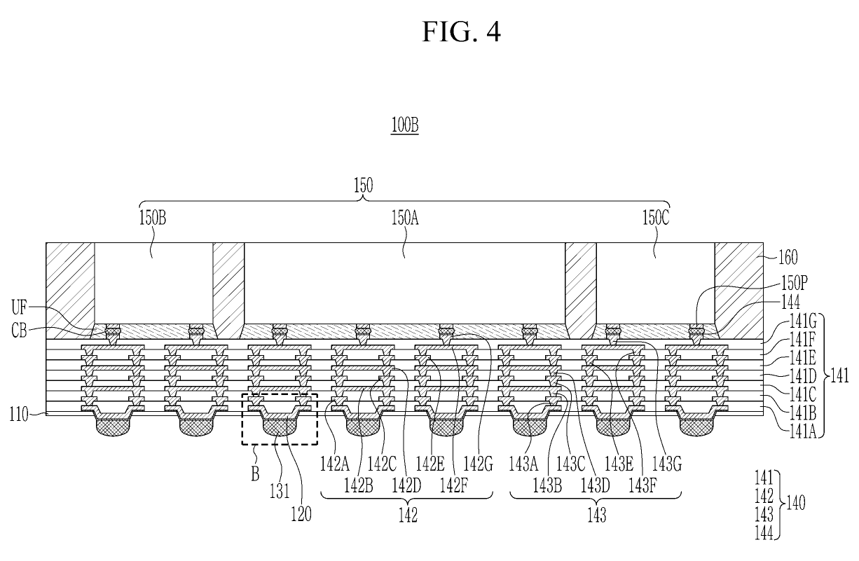

FIG. 4 is a cross-sectional view of a semiconductor package according to another embodiment.

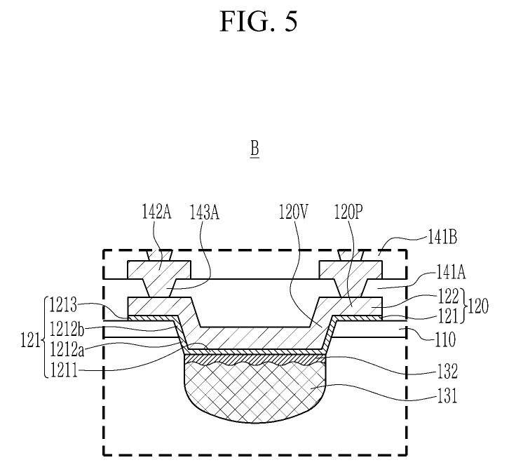

FIG. 5 is an enlarged view of a portion B of FIG. 4.

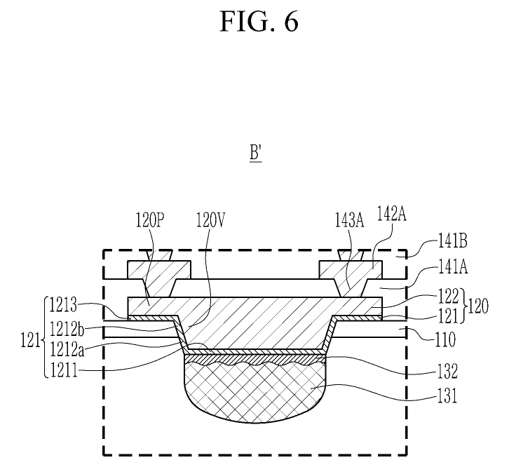

FIG. 6 is an enlarged view showing a portion B’ of a modified example corresponding to the portion B of FIG. 4.

Referring to the drawings, in a semiconductor package 100B according to another embodiment, a via 143 of a redistribution structure 140 may be staggered in the vertical direction with respect to the external connection terminal 131. Here, the vertical direction means the stacking direction of the redistribution structure 140, for example, the direction from one of the stacked insulating layers 141 to another insulating layer 141. At least the lowest via 143A that is closest to the external connection terminal 131 and connected to the under bump metallization 120 may be staggered in the vertical direction with respect to the external connection terminal 131. For example, the lowest via 143A may be in contact with the pad area 120P of the under bump metallization 120. The stress applied to the external connection terminal 131 of the semiconductor package 100B may be transmitted upward through the under bump metallization 120. By forming the via 143 so as to be staggered in the vertical direction from the external connection terminal 131, it is possible to prevent the stress transmitted from the external connection terminal 131 from being concentrated on the via 143.

In some embodiments, the via region 120V may be a plated via formed along the wall and bottom surfaces of the opening formed in the passivation layer 110, and the pad region 120P may have a shape (e.g., a ring shape) with a recess in the middle. In some embodiments, the via region 120V may be a field via that fills the opening formed in the passivation layer 110, and the pad region 120P may have a plate shape (e.g., a circular plate shape) with a filled center space (referring to FIG. 6).

In addition, the description of other components may be equally applied to the contents specifically described in the description of the semiconductor package 100A according to one embodiment of the present disclosure, unless specifically contradictory.

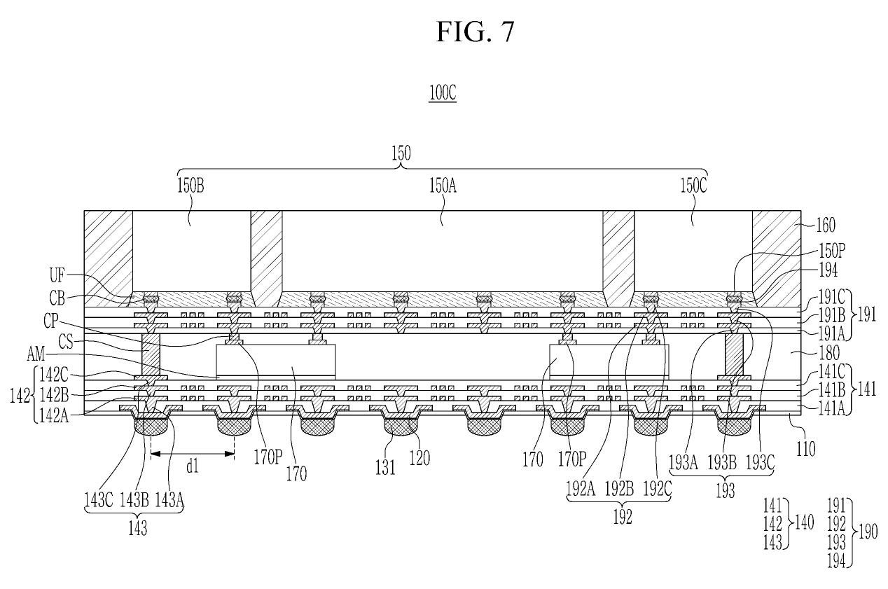

FIG. 7 is a cross-sectional view of a semiconductor package according to another embodiment.

Referring to FIG. 7, a semiconductor package 100C according to another embodiment includes a passivation layer 110, an under bump metallization 120, an external connection terminal 131, a first redistribution structure 140, a bridge die 170, a first encapsulant 180, a second redistribution structure 190, a semiconductor chip 150, and a second encapsulant 160.

Compared to the semiconductor package 100A, the first redistribution structure 140 of the semiconductor package 100C has a different number of layers from the redistribution structure 140 of the semiconductor package 100A and does not include a surface treatment layer 144.

The bridge die 170 may be placed on the upper surface of the first redistribution structure 140. The bridge die 170 may electrically connect two or more semiconductor chips 150. For example, the semiconductor package 100C may include the bridge die 170 illustrated on the left that electrically connects the first semiconductor chip 150A and the second semiconductor chip 150B and the bridge die 170 illustrated on the right that electrically connects the first semiconductor chip 150A and the third semiconductor chip 150C. A portion of each semiconductor chip 150 may overlap a portion the bridge die 170 in the thickness direction. The bridge die 170 may be manufactured by forming a wiring structure having a fine pitch on a semiconductor substrate (e.g., a silicon substrate). The bridge die 170 may have a shape that is approximately rectangular, such as a square or rectangle, but is not limited thereto. The bridge die 170 may include a bridge pad 170P, and may be disposed so that the surface on which the bridge pad 170P is disposed on the first redistribution structure 140 faces the semiconductor chips 150. A conductive material may be used as the material for the bridge pad 170P. For example, the bridge pad 170P may include a metal such as aluminum (Al), copper (Cu), titanium (Ti), tungsten (W), gold (Au), platinum (Pt), silver (Ag), tin (Sn), chromium (Cr), palladium (Pd), or an alloy of two or more of these.

The bridge die 170 may be attached to the first redistribution structure 140 via an adhesive member AM. For example, the adhesive member AM may be placed between the bridge die 170 and the uppermost insulating layer 141C of the first redistribution structure 140 to attach them to each other. As the material for the adhesive member AM, a substance having adhesive and insulating properties may be used. For example, a die attach film (DAF) may be used as the adhesive material AM.

The bridge die 170 can be electrically connected to the second redistribution structure 190 through a connecting pillar CP. In some embodiments, the connecting filler CP may physically and/or electrically connect the bridge pad 170P of the bridge die 170 to the lowest via 193A of the second redistribution structure 190. In some embodiments, the connecting filler CP may physically and/or electrically connect the bridge pad 170P of the bridge die 170 to a lowermost wiring layer (not shown) embedded in the lowermost insulating layer 191A of the second redistribution structure 190. The connecting filler CP may be placed on the bridge die 170 and embedded in a first encapsulant 180. A conductive material may be used as the material for the connecting filler CP. For example, the connecting filler CP may include a metal such as aluminum (Al), copper (Cu), titanium (Ti), tungsten (W), gold (Au), platinum (Pt), silver (Ag), tin (Sn), chromium (Cr), palladium (Pd), or an alloy of two or more of these.

The first encapsulant 180 may cover at least a portion of each of the bridge die 170, the connecting filler CP and the connecting structure CS. The upper surface of each of the connecting filler CP and the connecting structure CS may be exposed to the upper surface of the first encapsulant 180 for the electrical connection with the second redistribution structure 190. The upper surface of each of the connecting filler CP and the connecting structure (CS) can be exposed to the upper surface of the first encapsulant 180, for example, by grinding and removing a portion of the first encapsulant 180. The upper surface of each of the connecting filler CP and the connecting structure CS may be coplanar with the upper surface of the first encapsulant 180. An insulating material may be used as the material for the first encapsulant 180. For example, the first encapsulant 180 may include an epoxy molding compound (EMC). Alternatively, the first encapsulant 180 may include other insulating materials, such as a thermosetting resin such as epoxy, a thermoplastic resin such as polyimide (PI), etc. The process of molding the bridge die 170, the connecting filler CP and the connecting structure CS with the first encapsulant 180 may be performed by, for example, compression molding or transfer molding.

The second redistribution structure 190 may be placed on the first encapsulant 180 and be electrically connected to the bridge die 170 and the first redistribution structure 140. Additionally, the semiconductor chip 150 may be placed on the upper surface of the second redistribution structure 190 and electrically connected to the second redistribution structure 190. The second redistribution structure 190 may include an insulating layer 191, a wiring layer 192, and a via 193. For example, the second redistribution structure 190 includes a first insulating layer 191A, a first wiring layer 192A disposed on the first insulating layer 191A, a first via 193A penetrating the first insulating layer 191A and electrically connecting the connection pillar CP or the connection structure CS and the first wiring layer 192A, a second insulating layer 191B disposed on the first insulating layer 191A, a second wiring layer 192B disposed on the second insulating layer 191B, a second via 193B penetrating the second insulating layer 191B and electrically connecting the first wiring layer 192A and the second wiring layer 192B, a third insulating layer 191C disposed on the second insulating layer 191B, a third wiring layer 192C disposed on the third insulating layer 191C, and a third via 193C penetrating the insulating layer 191C and electrically connecting the second wiring layer 192B and the third wiring layer 192C. However, the number of layers of the second redistribution structure 190 may be less or more than that shown in the drawing. The number of layers of the second redistribution structure 190 may be the same as or different from the number of layers of the first redistribution structure 140. The description of the second redistribution structure 190 (including the description of the insulating layer 191, the wiring layer 192 and the via 193) may be applied identically to the description of the first redistribution structure 140 (including the description of the insulating layer 141, the wiring layer 142 and the via 143) unless otherwise specifically contradictory.

At least one surface treatment layer 194 may be placed on the uppermost wiring layer 192C that functions as a connection pad among the wiring layers 142. The surface treatment layer 194 may be composed of a single layer or multiple layers. For example, the surface treatment layer 194 may include a first surface treatment layer including nickel (Ni) and a second surface treatment layer disposed on the first surface treatment layer and including gold (Au). The first surface treatment layer may prevent a formation of an intermetallic compound (IMC) due to the diffusion between the uppermost wiring layer 192C and the second surface treatment layer, and the second surface treatment layer may prevent a surface oxidation of the uppermost wiring layer 192C and improve the electrical reliability.

The second redistribution structure 190 may be electrically connected to the first redistribution structure 140 through the connecting structure CS embedded in the first encapsulant 180. The connecting structure CS may be in contact with the first redistribution structure 140 and the second redistribution structure 190. In some embodiments, the connecting structure CS may physically and/or electrically connect the uppermost wiring layer 142C of the first redistribution structure 140 to the bottom via 193A of the second redistribution structure 190. In some embodiments, the connecting structure CS may physically and/or electrically connect the uppermost wiring layer 142C of the first redistribution structure 140 to a lowermost wiring layer (not shown) embedded in the lowermost insulating layer 191A of the second redistribution structure 190. The connecting structure CS may have a pillar shape, but may also have a ball shape such as a copper core solder ball (CCSB) according to an embodiment. A conductive material may be used as the material for the connecting structure CS. For example, the connecting structure CS may include a metal such as aluminum (Al), copper (Cu), titanium (Ti), tungsten (W), gold (Au), platinum (Pt), silver (Ag), tin (Sn), chromium (Cr), palladium (Pd), or an alloy of two or more of these. The connecting structure CS may be disposed in a form surrounding the bridge die 170, but is not limited thereto. There are no special restrictions on the shape, number, or spacing of the connecting structure CS.

In addition, the description of other components may be equally applied to the contents specifically described in the description of the semiconductor package 100A according to one embodiment of the present disclosure, unless specifically contradictory.

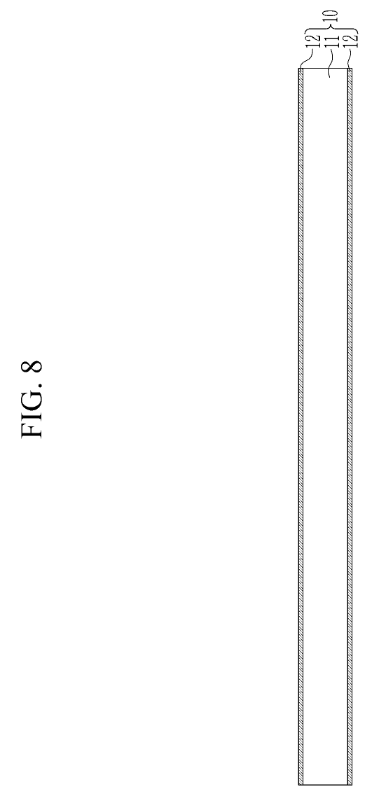

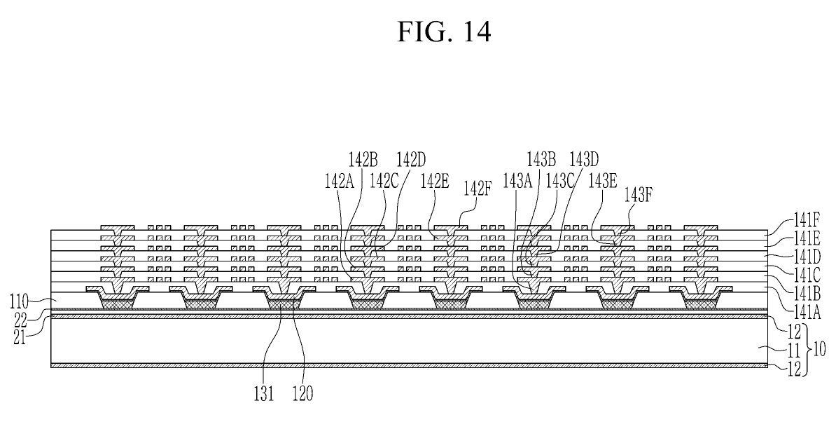

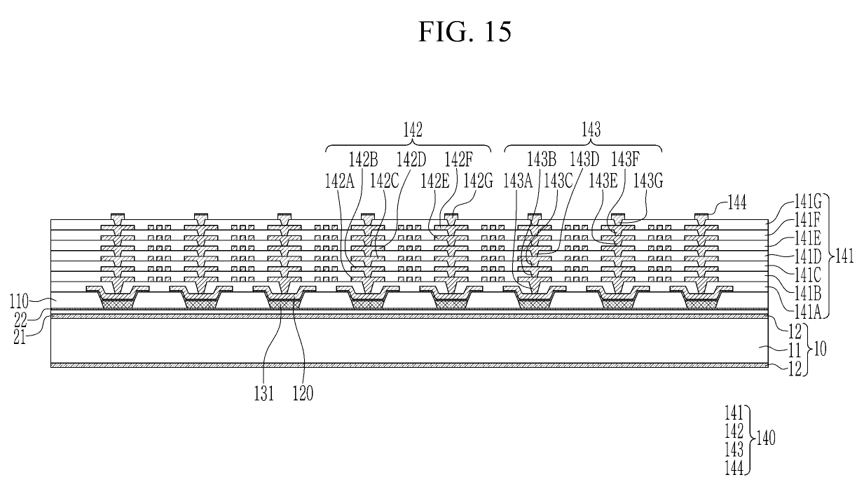

FIGS. 8 to 23 are cross-sectional views sequentially showing a method for manufacturing a semiconductor package according to one embodiment.

In a manufacturing method of a semiconductor package according to the present disclosure, an external connection terminal 131 and an under bump metallization 120 are first formed, then a redistribution structure 140 is formed on these, and a semiconductor chip 150 is placed on the redistribution structure 140. According to the present disclosure, by sequentially forming the external connection terminal 131 and the under bump metallization 120 within the same opening of the passivation layer 110, the alignment therebetween may be improved. The external connection terminal 131 and the under bump metallization 120 are formed before the mounting of the semiconductor chip 150, so even if a defect occurs during the manufacturing process of the external connection terminal 131 and the under bump metallization 120, the cost loss due to the defect may be reduced by discarding only a part of the package excluding the semiconductor chip 150. In addition, since a seed layer 121 is formed between the passivation layer 110 and the conductive layer 122, the interfacial adhesion between the under bump metallization 120 and the passivation layer 110 is strengthened, thereby improving the reliability. In addition, the process may be simplified by forming the external connection terminal 131 and the under bump metallization 120 by forming the opening 110h in the passivation layer 110 and filling the opening with a conductive material in a manner similar to the method of forming a redistribution structure 140.

Below, the method for manufacturing the semiconductor package according to one embodiment will be described in order with reference to the drawings.

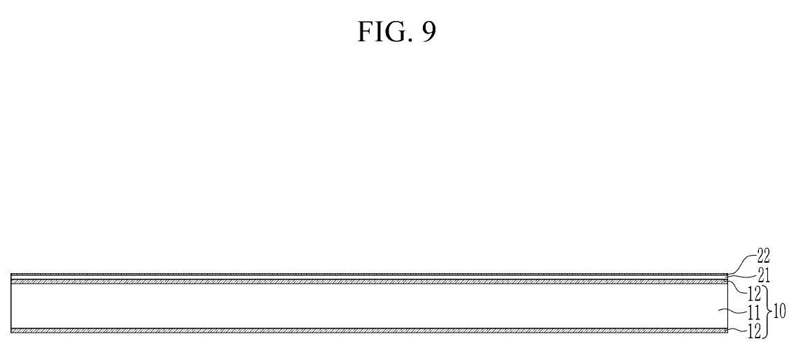

First, referring to FIG. 8 and FIG. 9, a first passivation layer 21 is formed on a carrier substrate 10, and a first seed layer 22 is formed on the first passivation layer 21. The carrier substrate 10 may include an insulating core layer 11 and a conductive thin film layer 12 disposed on at least one surface of the insulating core layer 11. For example, the carrier substrate 10 may be a dual copper film (DCF) including a Cu thin film layer disposed on both sides of an insulating core layer.

When the first seed layer 22 and the external connection terminal 131 are directly formed on the carrier substrate 10, the first seed layer 22 may react with the conductive thin film layer 12 of the carrier substrate 10 due to heat applied during the mounting process (e.g., a thermal compression or a mass reflow process) of the semiconductor chip 150, making it difficult to detach the carrier substrate 10. In addition, when the first seed layer 22 is directly formed on the carrier substrate 10, an arc may occur within a sputtering equipment due to the conductive thin film layer 12 of the carrier substrate 10. In the present disclosure, the first passivation layer 21 is introduced on the carrier substrate 10, thereby facilitating the separation of the carrier substrate 10 and preventing the arc generation due to the sputtering on a large-area metal.

The first passivation layer 21 may be formed on the conductive thin film layer 12 of the carrier substrate 10. The first passivation layer 21 can be formed through a deposition process such as chemical vapor deposition (CVD), atomic layer deposition (ALD), or physical vapor deposition (PVD), but is not limited thereto. An insulating material can be used as the material for the first passivation layer 21. In some embodiments, the first passivation layer 21 may include a PID, similar to the second passivation layer 110. The first passivation layer 21 may be removed in a subsequent process and may be formed with a thin thickness for a removal efficiency. For example, the first passivation layer 21 may be formed with the thinner thickness than the second passivation layer 110.

The first seed layer 22 may be formed by a physical vapor deposition (PVD), for example, a sputtering. A conductive material (e.g., a metal or an alloy of metals) may be used as the material for the first seed layer 22, and preferably, a conductive material having the excellent adhesion to the first passivation layer 21 may be used. For example, the first seed layer 22 may include titanium (Ti). In some embodiments, the first seed layer 22 may have a Ti/Cu structure including a titanium (Ti) layer and a copper (Cu) layer disposed on the titanium layer.

Next, referring to FIG. 10, a second passivation layer 110 is formed on the first seed layer 22, and an opening 110h penetrating the second passivation layer 110 is formed.

The second passivation layer 110 may be formed through a deposition process such as a chemical vapor deposition (CVD), an atomic layer deposition (ALD), or a physical vapor deposition (PVD), but is not limited thereto. The second passivation layer 110 may be formed with a thickness thicker than the insulating layer 141 of the redistribution structure 140, but is not limited thereto.

The opening 110h may be formed to penetrate between the upper and lower surfaces of the second passivation layer 110. When forming the opening 110h, the first seed layer 22 may be exposed on the bottom surface of the opening 110h. In order to form the external connection terminal 131 and the under bump metallization 120 having a fine pitch, the opening 110h may be formed by a photolithography process. However, the opening 110h may be formed by other methods such as a laser processing. The opening 110h may be formed so that the width thereof narrows from the upper side to the lower side. By appropriately controlling process conditions such as exposure conditions (e.g., a light amount, a wavelength) and development conditions (e.g., a developer concentration, a development time) when forming the opening 110h, the opening 110h having the width that narrows from the upper side to the lower side may be formed. When the width of the opening 110h is formed to narrow from the upper side to the lower side, the interfacial adhesion between the passivation layer 110 and the under bump metallization 120 may be improved.

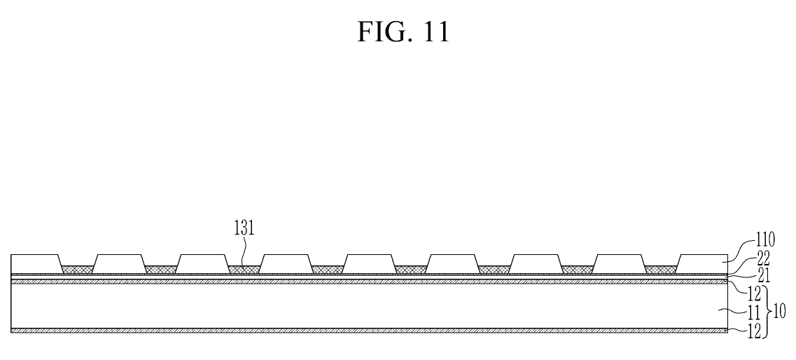

Next, referring to FIG. 11, an external connection terminal 131 is formed that fills a part of the opening 110h. The external connection terminal 131 may be formed by a plating. When forming the external connection terminal 131, the first seed layer 22 may function as a bus line, and the external connection terminal 131 may be formed directly on the first seed layer 22.

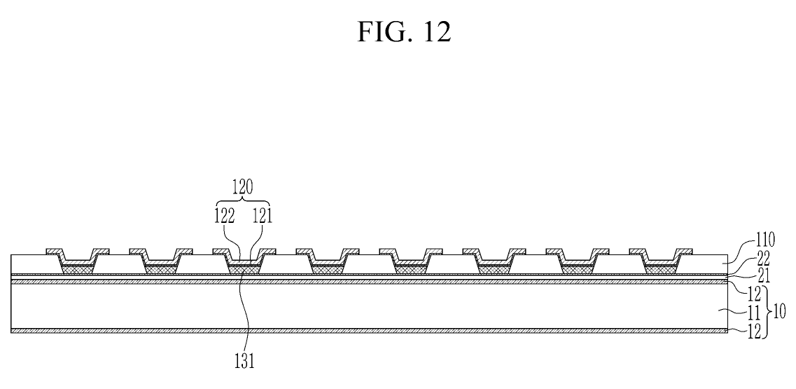

Next, referring to FIG. 12, an under bump metallization 120 is formed that fills the other part of the opening 110h and extends onto the second passivation layer 110. The under bump metallization 120 may include at least one of a plating process and a deposition process. For example, the under bump metallization 120 may be manufactured by forming a second seed layer 121 by a deposition process so that it covers the external connection terminal 131 and the wall surface of the opening 110h and extends onto the second passivation layer 110, and forming a conductive layer 122 on the second seed layer 121 by a deposition process or a plating process. The thickness of the second seed layer 121 may be thinner than the thickness of the conductive layer 122.

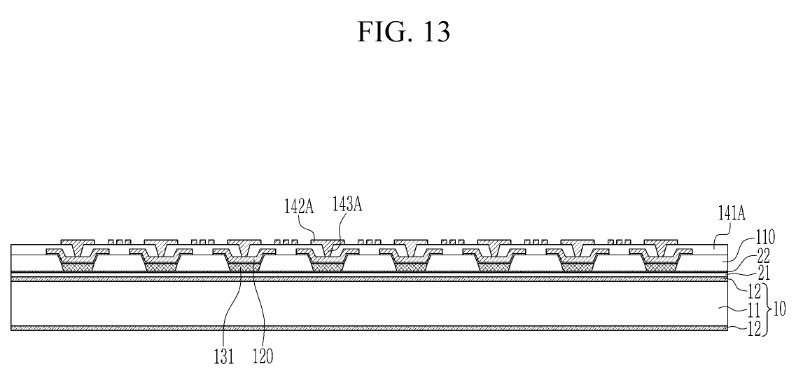

Next, referring to FIGS. 13-15, a redistribution structure 140 is formed to cover the under bump metallization 120 on the passivation layer 110. The redistribution structure 140 may be manufactured by sequentially and repeatedly forming an insulating layer 141, a via 143, and a wiring layer 142 on the passivation layer 110. For example, the redistribution structure 140 may be manufactured by repeatedly forming the insulating layer 141, forming the via hole in the insulating layer 141, and then forming the via 143 and the wiring layer 142 to fill the via hole and extend onto the insulating layer 141. At least one surface treatment layer 144 may be formed on the uppermost wiring layer 142G that functions as a connection pad among the wiring layers 142.

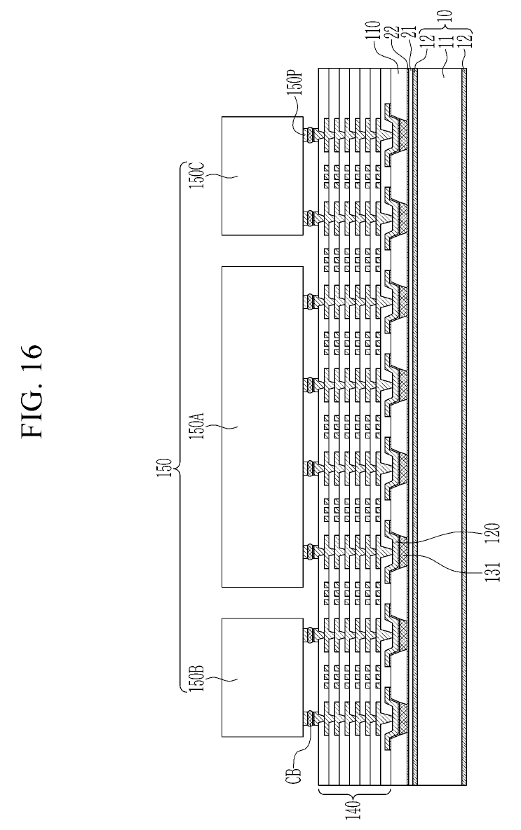

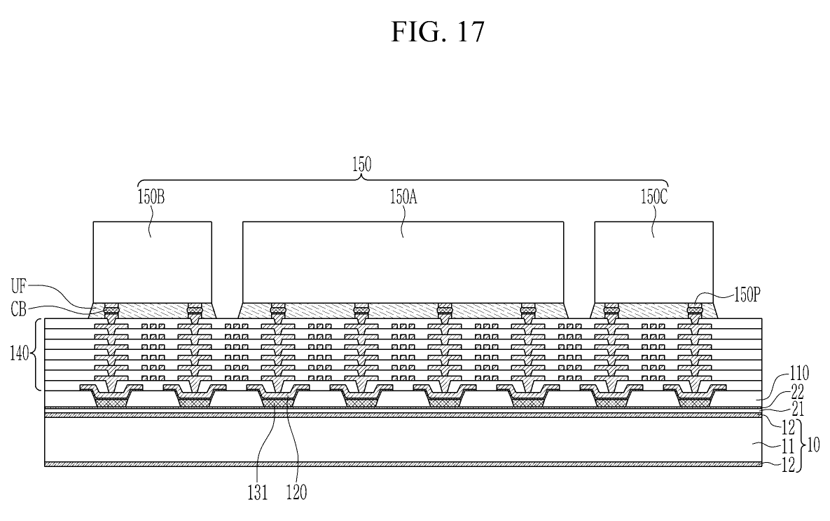

Next, referring to FIG. 16 and FIG. 17, semiconductor chips 150 are placed on the redistribution structure 140. The semiconductor chips 150 may be placed in a face-down configuration so that the active surface on which the connection pads 150P are placed faces the redistribution structure 140. In some embodiments, the semiconductor chips 150 may be mounted on the redistribution structure 140 via chip bumps CB disposed on the lower surface. The space between the redistribution structure 140 and the semiconductor chip 150 may be filled with an underfill resin UF. The underfill resin UF may be filled into the space between the redistribution structure 140 and the semiconductor chip 150, for example, through a capillary underfill process. The filled underfill resin UF may cover the chip bumps CB.

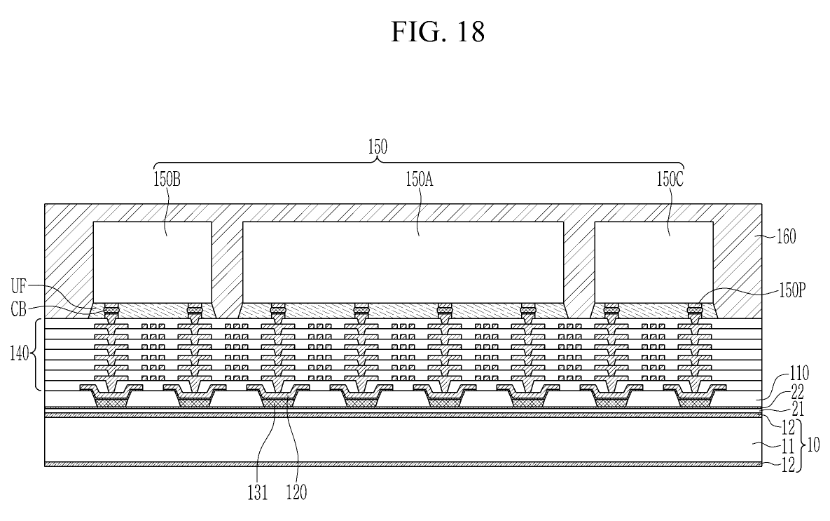

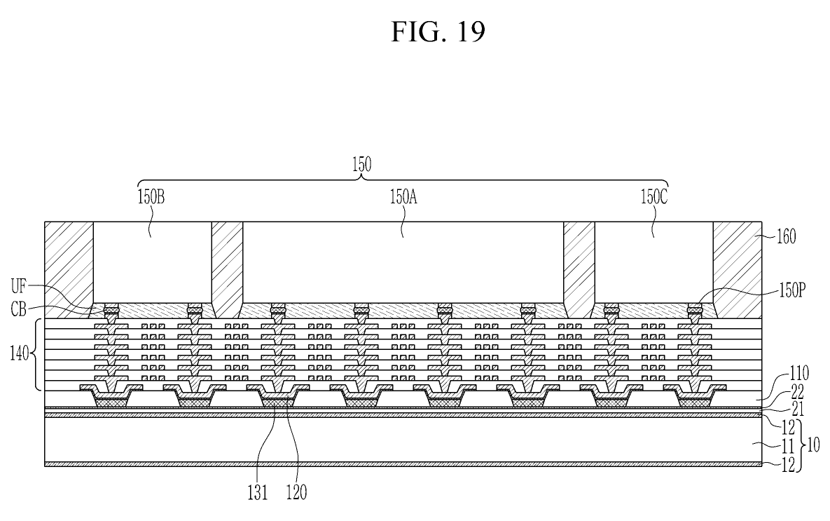

Next, referring to FIG. 18 and FIG. 19, an encapsulant 160 covering semiconductor chips 150 is formed. The process of molding the semiconductor chips 150 with the encapsulant 160 may be performed, for example, by a compression molding or a transfer molding. According to the embodiment, the upper area of the encapsulant 160 may be ground and removed to expose the upper surface of the semiconductor chip 150. By exposing the upper surface of the semiconductor chip 150 to the upper surface of the encapsulant 160, the heat dissipation characteristics of the semiconductor package 100A may be improved.

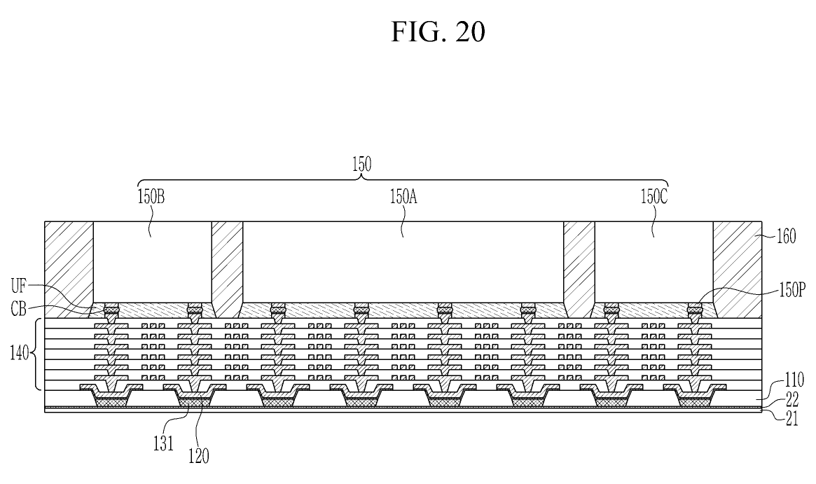

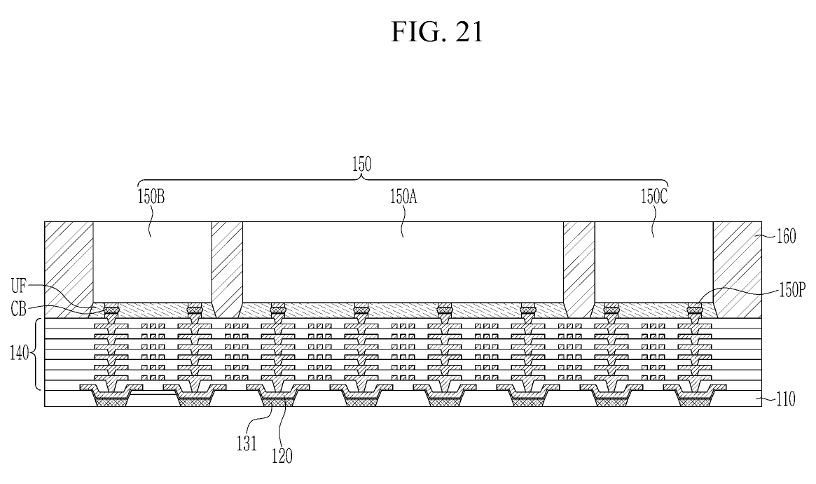

Next, referring to FIG. 20 and FIG. 21, the carrier substrate 10 is separated from the first passivation layer 21, and the first passivation layer 21 and the first seed layer 22 are sequentially removed. The first passivation layer 21 is not limited thereto, but may be removed by a dry etching, similar to the second passivation layer 110. The first seed layer 22 is not limited thereto, but may be removed by a wet etching or dry etching.

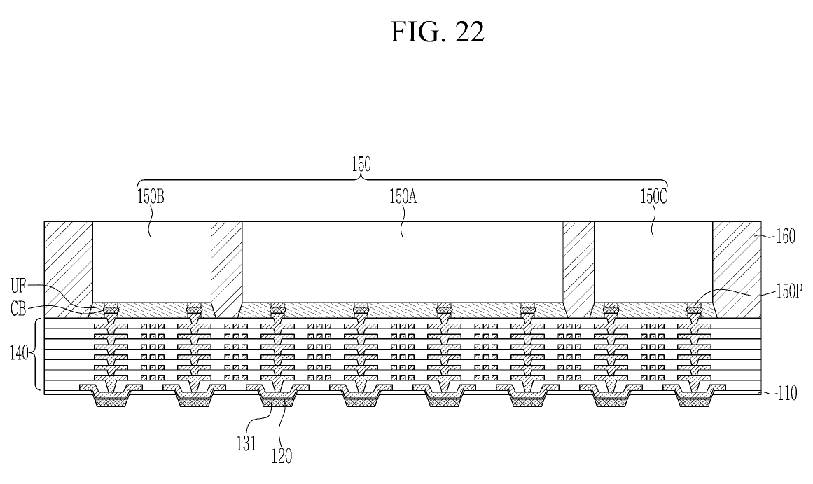

Next, referring to FIG. 22, a portion of the second passivation layer 110 is removed so that the external connection terminal 131 is exposed. The second passivation layer 110 may be removed by a dry etching such as a plasma etching. When applying dry etching, the removal depth of the second passivation layer 110 in the vertical direction can be controlled by appropriately adjusting RF power, etching time, gas composition, etc. Since it may be difficult to control the removal depth of the second passivation layer 110 through a laser processing without introducing a separate stopper layer such as Cu, it may be appropriate to process the second passivation layer 110 through a dry etching.

In the step of removing a portion of the second passivation layer 110, a portion of the under bump metallization 120 may be exposed together with the external connection terminal 131. For example, the lower side of the under bump metallization 120 (e.g., the lower side of the via region 120V) may be exposed together with the external connection terminal 131, and the lower area of the under bump metallization 120 may protrude from the lower surface of the second passivation layer 110. In the step of removing a portion of the second passivation layer 110, all or a portion of the second-first region 1212a (referring to FIG. 2) may be removed. Depending on the vertical removal depth of the second passivation layer 110, the under bump metallization 120 may not be exposed and may be buried in the second passivation layer 110.

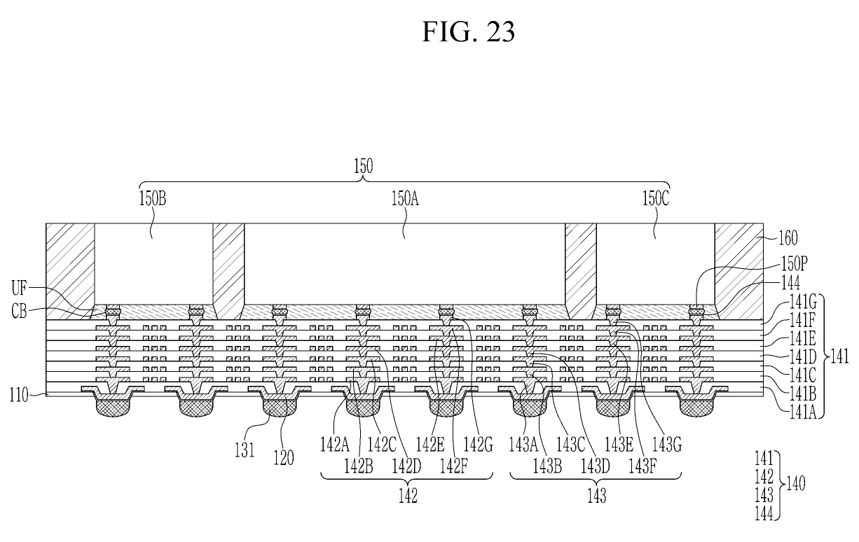

Next, referring to FIG. 23, the external connection terminal 131 is reflowed so that the lower surface of the external connection terminal 131 becomes round. After the reflow process of the external connection terminal 131, the lower surface of the external connection terminal 131 may have an approximate dome shape. According to an embodiment, an additional step of applying a flux before the reflow of the external connection terminal 131 may be performed. Additionally, a deflux process may be additionally performed to remove a flux residue after the reflow of the external connection terminal 131.

The present disclosure provides another embodiment of a manufacturing method of a semiconductor package including forming an external connection terminal; forming an under bump metallization on the external connection terminal; forming a redistribution structure on the under bump metallization; and placing a semiconductor chip on the redistribution structure.

In the manufacturing method of the semiconductor package, the external connection terminal may be formed by plating.

In the manufacturing method of the semiconductor package, forming the under bump metallization may include at least one of a plating process and a deposition process.

The manufacturing method of the semiconductor package may further include reflowing the external connection terminal.

The present disclosure provides another embodiment of a manufacturing method of a semiconductor package including: forming a passivation layer; forming an opening penetrating the passivation layer; forming an external connection terminal filling a portion of the opening; forming an under bump metallization filling another portion of the opening and extending onto the passivation layer; forming a redistribution structure covering the under bump metallization on the passivation layer; disposing a semiconductor chip on the redistribution structure; and removing a portion of the passivation layer so that the external connection terminal is exposed.

In the manufacturing method of the semiconductor package, the opening may be formed by a photolithography process.

In the manufacturing method of the semiconductor package, the opening may be formed so that a width of the opening narrows in a direction from an upper side to a lower side.

In the manufacturing method of the semiconductor package, a portion of the passivation layer may be removed by a dry etching.

In the removing of a portion of the passivation layer in the manufacturing method of the semiconductor package, a portion of the under bump metallization may be exposed together with the external connection terminal.

The present disclosure is another embodiment of a manufacturing method of a semiconductor package including forming a first passivation layer on a carrier substrate; forming a first seed layer on the first passivation layer; forming a second passivation layer on the first seed layer; forming an opening penetrating the second passivation layer; forming an external connection terminal filling a portion of the opening; forming an under bump metallization filling another portion of the opening and extending onto the second passivation layer; forming a redistribution structure on the second passivation layer covering the under bump metallization; placing a semiconductor chip on the redistribution structure; separating the carrier substrate; removing the first passivation layer; removing the first seed layer; and removing a portion of the second passivation layer so that the external connection terminal is exposed.

In the manufacturing method of the semiconductor package, the carrier substrate may include an insulating core layer and a conductive thin film layer disposed on at least one surface of the insulating core layer, and the first passivation layer may be formed on the conductive thin film layer.

In the manufacturing method of the semiconductor package, the first seed layer may include titanium.

In the manufacturing method of the semiconductor package, the external connection terminal may be formed by plating.

The manufacturing method of the semiconductor package may further include reflowing the external connection terminal.

In the manufacturing method of the semiconductor package, forming the under bump metallization may include forming a second seed layer that covers the external connection terminal and a wall surface of the opening and extends onto the second passivation layer, and forming a conductive layer on the second seed layer.

In the semiconductor package manufacturing method, the second seed layer may include titanium.

In the manufacturing method of the semiconductor package, the first passivation layer may be removed by a dry etching.

In the manufacturing method of the semiconductor package, a portion of the second passivation layer may be removed by a dry etching.

In the manufacturing method of the semiconductor package, in removing a portion of the second passivation layer, a portion of the under bump metallization may be exposed together with the external connection terminal.

The manufacturing method of the semiconductor package may further include forming an encapsulant covering at least a portion of the semiconductor chip.

Although the embodiments of the present disclosure have been described in detail above, the scope of the present disclosure is not limited thereto, and various modifications and improvements made by those skilled in the art using the basic concepts of the present disclosure defined in the following claims also fall within the scope of the present disclosure.

In addition, the embodiments of the present disclosure are not independent of each other and may be implemented in combination with each other unless there is a specific contradiction. Accordingly, embodiments in which the embodiments of the present disclosure are combined should also be considered to be included in the present disclosure.

What is claimed is:

1. A semiconductor package comprising:
a passivation layer;
an under bump metallization including a seed layer and a conductive layer disposed on the seed layer, the under bump metallization penetrating the passivation layer and extending onto an upper surface of the passivation layer;
an external connection terminal disposed on a lower surface of the under bump metallization;
a redistribution structure disposed on the upper surface of the passivation layer and covering the under bump metallization; and
a semiconductor chip disposed on an upper surface of the redistribution structure,
wherein the seed layer includes a first region disposed between the external connection terminal and the conductive layer and a second region disposed between the passivation layer and the conductive layer.

2. The semiconductor package of claim 1, wherein:
the under bump metallization protrudes from a lower surface of the passivation layer.

3. The semiconductor package of claim 2, wherein:
the seed layer further includes a third region connecting the first region and the second region.

4. The semiconductor package of claim 1, further comprising:
an intermetallic compound disposed between the under bump metallization and the external connection terminal.

5. The semiconductor package of claim 1, wherein:
the first region is in contact with the external connection terminal.

6. The semiconductor package of claim 1, wherein:
the redistribution structure includes an insulating layer integrally covering the under bump metallization on the passivation layer and a wiring layer disposed on the insulating layer and electrically connected to the under bump metallization.

7. The semiconductor package of claim 6, wherein:
the redistribution structure further includes a via penetrating the insulating layer and electrically connecting the under bump metallization to the wiring layer.

8. The semiconductor package of claim 7, wherein:
the via is staggered with respect to the external connection terminal in a vertical direction.

9. The semiconductor package of claim 7, wherein:
the via is in contact with the under bump metallization.

10. The semiconductor package of claim 1, wherein:
a width of the under bump metallization narrows from an upper side to a lower side in a direction towards the external connection terminal.

11. The semiconductor package of claim 1, wherein:
the passivation layer includes a photo imageable dielectric.

12. The semiconductor package of claim 1, wherein:
the seed layer includes titanium.

13. A semiconductor package, comprising:
a passivation layer;
a plurality of under bump metallizations including a seed layer and a conductive layer disposed on the seed layer, the plurality of under bump metallizations penetrating the passivation layer and extending onto an upper surface of the passivation layer;
a plurality of external connection terminals disposed on a lower surface of the plurality of under bump metallizations and electrically connected to the plurality of under bump metallizations, respectively;
a redistribution structure disposed on an upper surface of the passivation layer, covering the plurality of under bump metallizations, and electrically connected to the plurality of under bump metallizations;
a plurality of semiconductor chips disposed side by side on an upper surface of the redistribution structure; and
an encapsulant covering at least a portion of each of the plurality of semiconductor chips,
wherein the redistribution structure electrically connects two or more of the plurality of semiconductor chips, and
the seed layer includes a first region disposed between each of the plurality of external connection terminals and the conductive layer, and a second region disposed between the passivation layer and the conductive layer.

14. The semiconductor package of claim 13, wherein:
a distance between centers of adjacent external connection terminals among the plurality of external connection terminals in a cross section is 130 µm or less.

15. The semiconductor package of claim 13, wherein:
the plurality of under bump metallizations protrude from a lower surface of the passivation layer.

16. A semiconductor package, comprising:
a passivation layer;
a plurality of under bump metallizations including a seed layer and a conductive layer disposed on the seed layer, the plurality of under bump metallizations penetrating the passivation layer and extending onto an upper surface of the passivation layer;
a plurality of external connection terminals disposed on a lower surface of the plurality of under bump metallizations and electrically connected to the plurality of under bump metallizations, respectively;
a first redistribution structure disposed on an upper surface of the passivation layer, covering the plurality of under bump metallizations, and electrically connected to the plurality of under bump metallizations;
a bridge die disposed on an upper surface of the first redistribution structure;
a first encapsulant covering at least a portion of the bridge die;
a second redistribution structure disposed on the first encapsulant and electrically connected to the bridge die and the first redistribution structure;
a plurality of semiconductor chips disposed side by side on an upper surface of the second redistribution structure and electrically connected to the second redistribution structure; and
a second encapsulant covering at least a portion of each of the plurality of semiconductor chips,
wehrein the bridge die electrically connects two or more of the plurality of semiconductor chips, and
the seed layer includes a first region disposed between each of the plurality of external connection terminals and the conductive layer, and a second region disposed between the passivation layer and the conductive layer.

17. The semiconductor package of claim 16, wherein:
a distance between centers of adjacent external connection terminals among the plurality of external connection terminals in a cross section is 130 µm or less.

18. The semiconductor package of claim 16, wherein:
the plurality of under bump metallizations protrude from a lower surface of the passivation layer.

19. The semiconductor package of claim 16, further comprising:
a connecting structure embedded in the first encapsulant and electrically connecting the first redistribution structure to the second redistribution structure.

20. The semiconductor package of claim 16, further comprising:
a connecting filler embedded in the first encapsulant and electrically connecting the bridge die to the second redistribution structure.
